(19) United States
(12) Patent Application Publication
(10) Pub. No.: US 2012/0175772 A1
(43) Pub. Date: Jul. 12, 2012

(54) ALTERNATIVE SURFACE FINISHES FOR FLIP-CHIP BALL GRID ARRAYS

(76) Inventors: Andrew K. Leung, Markham (CA); Neil Mclellan, Ontario (CA)

(21) Appl. No.: 12/986,584

(22) Filed: Jan. 7, 2011

(51) Int. Cl. H01L 23/488; H01L 21/60

(52) U.S. Cl. 257/738; 438/614; 257/E23.023; 257/E21.507

(57) ABSTRACT

A ball grid array package device includes a substrate with a copper ball grid array pad formed on the substrate. A nickel layer may be formed on the copper pad and a tin layer formed on the nickel layer. The nickel layer may be formed using an electroless nickel plating process. The tin layer may be formed using an immersion tin process. In some cases, silver may be used instead of tin and formed using an immersion silver process.

### BACKGROUND OF THE INVENTION

1. Field of the Invention

This invention relates generally to a structure used in a ball grid array package and, more specifically, to a surface finish for a ball grid array pad.

2. Description of the Related Art

Ball grid arrays (BGAs) are packages widely used for surface mounting of integrated circuits (ICs) to printed circuit boards (PCBs). One variant of a BGA that can be used is a flip chip ball grid array (FCBGA). A BGA package typically has a pattern of copper pads on top of the IC substrate surrounded by a solder mask. Solder (e.g., solder balls) is placed on top of the copper pads. The BGA is then placed on the PCB, which has a matching pattern of copper pads. The BGA/PCB assembly is then heated to melt the solder and allow the solder to flow in the pattern before cooling the assembly to re-solidify the solder.

A key issue in the bonding of the solder to the copper pad. Copper does not easily bond to most lead-free solders. To overcome the bonding issue between lead-free solder and copper, a surface finish is provided on the copper pad to promote adhesion between the pad and the solder. Current industrial lead-free soldering surface finishes include organic solderability preservative (OSP), electroless nickel/immersion gold (ENIG), electroless nickel/electroless palladium/immersion gold (ENEPIG), immersion silver, and immersion tin.

FIG. 1 depicts a cross-sectional view of BGA pad 100 with an ENIG surface finish. Pad 100 is a copper pad placed on substrate 102 and surrounded by solder mask 104. For ENIG, electroless nickel layer 106 is formed on pad 100 followed by immersion gold layer 108 as the top layer. Gold layer 108 typically has a thickness between about 2 microns and about 6 microns. Gold provides a good electrical conductivity and surface protection. Gold, however, is an expensive material that can add significant cost to manufacturing the BGA package over using such materials as tin or silver.

Replacing some of the gold with a less expensive material may reduce costs for manufacturing the BGA package. FIG. 2 depicts a cross-sectional view of BGA pad 100 with an ENEPIG surface finish. For ENEPIG, electroless palladium layer 110 is placed between nickel layer 106 and gold layer 108. Using palladium may allow for the reduction of the thickness of gold layer 108 to about 0.05 microns. Palladium, however, may still be more expensive than other conducting materials such as tin.

FIG. 3 depicts a cross-sectional view of BGA pad 100 with an immersion tin surface finish. Immersion tin layer 112 is formed on copper pad 100. Tin may be much less expensive to use than gold and/or palladium for the BGA package. Tin layer 112 may be formed on copper pad 100 using a simple coating process. Tin layer 112 provides good surface protection for copper pad 100. Tin and copper, however, may be susceptible to intermetallic growth. For example, copper may diffuse into tin during subsequent processing such as plating. The intermetallic growth may degrade the BGA package over time and provide reduced reliability of the package.

Thus, there is a need for a surface finish for copper pads in a BGA package that is low cost and provides long term reliability for bonding between the copper pads and lead-free solder. The surface finish may also be easily manufacturable and/or be easily integrated into current packaging techniques.

### SUMMARY OF EMBODIMENTS OF THE INVENTION

In certain embodiments, a ball grid array package device includes a substrate with a copper ball grid array pad formed on the substrate. A nickel layer may be formed on the copper pad and a tin layer formed on the nickel layer. The nickel layer may be formed using an electroless nickel plating process. The tin layer may be formed using an immersion tin process.

In some embodiments, a ball grid array package device includes a substrate with a copper ball grid array pad formed on the substrate. A nickel layer may be formed on the copper pad and a silver layer formed on the nickel layer. The nickel layer may be formed using an electroless nickel plating process. The silver layer may be formed using an immersion silver process.

The nickel layer may be an intermetallic diffusion barrier between the copper pad and either the tin or silver layer. The tin or silver layer allows the ball grid array package device to be bonded to lead-free solder. Lead-free solder may be used to bond the ball grid array package device to, for example, a printed circuit board or a printed wiring board. In some embodiments, palladium is formed between the nickel layer and either the tin or silver layer.

### BRIEF DESCRIPTION OF THE DRAWINGS

FIG. 1 depicts a cross-sectional view of BGA pad 100 with an electroless nickel/immersion gold (ENIG) surface finish.

FIG. 2 depicts a cross-sectional view of BGA pad 100 with an electroless nickel/electroless palladium/immersion gold (ENEPIG) surface finish.

FIG. 3 depicts a cross-sectional view of BGA pad 100 with an immersion tin surface finish.

FIG. 4 depicts a cross-sectional view of an embodiment of BGA pad 100 with a nickel/tin surface finish.

FIG. 5 depicts a cross-sectional view of BGA pad 100 with a nickel/silver surface finish.

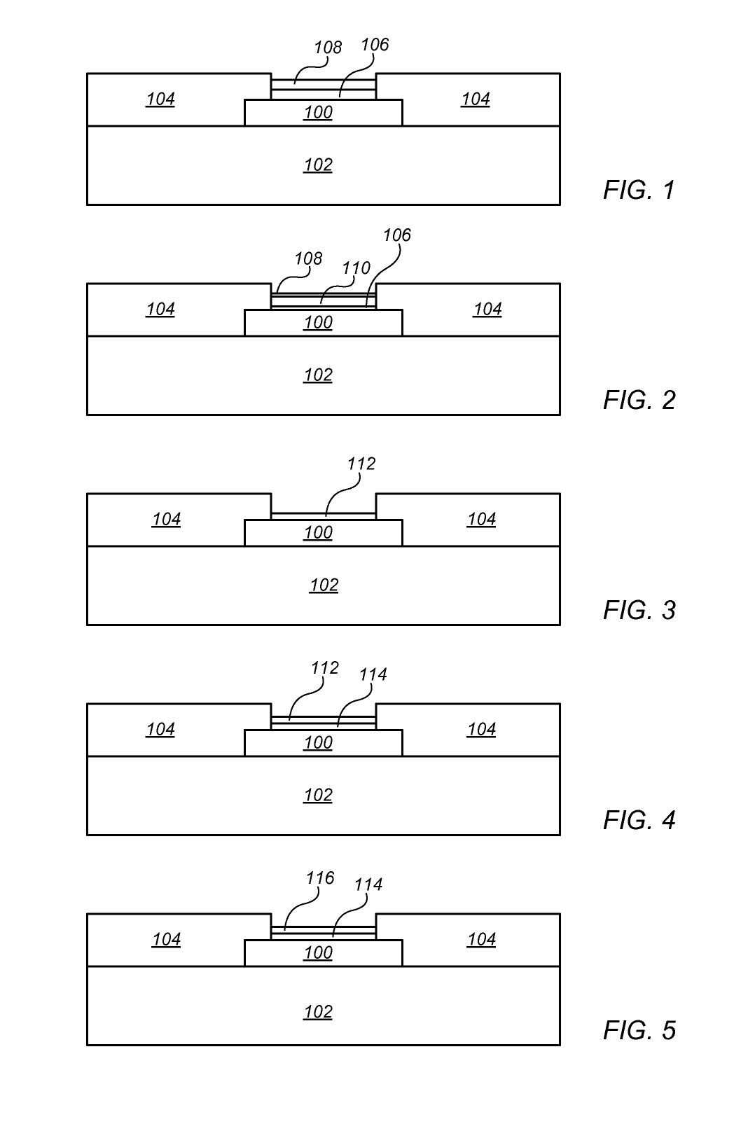

While the invention is described herein by way of example for several embodiments and illustrative drawings, those skilled in the art will recognize that the invention is not limited to the embodiments or drawings described. It should be understood that the drawings and detailed description hereto are not intended to limit the invention to the particular form disclosed, but on the contrary, the invention is to cover all modifications, equivalents and alternatives falling within the spirit and scope of the present invention as defined by the appended claims. Any headings used herein are for organizational purposes only and are not meant to limit the scope of the description or the claims. As used herein, the word “may” is used in a permissive sense (i.e., meaning having the potential to) rather than the mandatory sense (i.e. meaning must). Similarly, the words “include”, “including”, and “includes” mean including, but not limited to.

### DETAILED DESCRIPTION OF THE EMBODIMENTS

FIG. 4 depicts a cross-sectional view of an embodiment of BGA pad 100 with a nickel/tin surface finish. In some embodiments, pad 100 is a flip-chip ball grid array (FCBGA) pad or a controlled collapse chip connection pad (C4 pad). Pad 100 is formed on substrate 102. In certain embodiments, pad 100 is a copper pad. Substrate 102 may be, for example, a buried oxide layer substrate or other semiconductor device substrate. Solder mask 104 may be formed on substrate 102 at and around the edges of pad 100, as shown in FIG. 4.

In certain embodiments, nickel layer 114 is formed (deposited) between on pad 100. In some embodiments, nickel layer 114 is formed using an electroless nickel (EN) process (e.g., an auto-catalytic nickel plating process) or another suitable nickel plating process. After forming nickel layer 114, tin layer 112 may be formed on the nickel layer. In certain embodiments, tin layer 112 is formed using an immersion tin (IT) process. Thus, nickel layer 114 and tin layer 112 may be formed in an electroless nickel/immersion tin (ENIT) process. In some embodiments, tin layer 112 is formed using an electroless tin (ET) process. Thus, nickel layer 114 and tin layer 112 may be formed in an electroless nickel/electroless tin (ENET) process.

The thickness of nickel layer 114 may be selected based on factors such as, but not limited to, a thickness needed to inhibit intermetallic diffusion between copper in pad 100 and tin layer 112, and a thickness that provides suitable electrical and/or mechanical performance for the BGA package. For example, nickel layer 114 may have a minimum thickness that is needed to inhibit intermetallic diffusion between copper in pad 100 and tin layer 112. At the same time, however, nickel layer 114 may not have a thickness so large that the amount of nickel present in the BGA package degrades electrical and/or mechanical properties of the package. In certain embodiments, nickel layer 114 has a thickness between about 5 microns and about 10 microns.

Tin layer 112 may have at least a minimum thickness that inhibits the tin layer from unbonding from solder during BGA package assembly. Similar to nickel layer 114, tin layer 112 may not have a large thickness that could potentially degrade electrical and/or mechanical properties of the BGA package. In certain embodiments, tin layer 112 has a thickness between about 1 micron and about 3 microns or between about 1 micron and about 5 microns.

In some embodiments, silver is used as the top layer of the surface finish. FIG. 5 depicts a cross-sectional view of an embodiment of BGA pad 100 with a silver/tin surface finish. Silver layer 116 is formed on nickel layer 114 above pad 100. In certain embodiments, silver layer 116 is formed using an immersion silver (IS) process. Thus, nickel layer 114 and silver layer 116 may be formed in an electroless nickel/immersion silver (ENIS) process. In certain embodiments, silver layer 116 is formed using an electroless silver (ES) process. Thus, nickel layer 114 and silver layer 116 may be formed in an electroless nickel/electroless silver (ENES) process.

As for tin, silver layer 116 may have at least a minimum thickness that inhibits the silver layer from unbonding from solder during BGA package assembly. In addition, silver layer 116 may not have a large thickness that could potentially degrade electrical and/or mechanical properties of the BGA package. In certain embodiments, silver layer 116 has a thickness between about 1 micron and about 5 microns.

For the embodiments depicted in FIGS. 4 and 5, nickel layer 114 provides a barrier that minimizes intermetallic diffusion between tin layer 112, or silver layer 114, and copper pad 100. Providing the intermetallic diffusion barrier with nickel allows a reliable, low cost BGA package to be produced with either tin or silver. For example, using tin or silver may reduce costs by between about 10% and about 20% as compared to using gold or gold and palladium.

Using either tin layer 112 or silver layer 114 as the top layer of the surface finish of pad 100 allows oxides and/or other contaminants to be removed by solder flux and/or other methods. Removal of contaminants such as oxides inhibits the contaminants from adversely affecting the soldering process or the bond between the solder and the top layer of the surface finish.

In certain embodiments, the use of nickel layer 114 and either tin layer 112 or silver layer 114 allows the thickness of copper pad 100 to be reduced while maintaining desired electrical performance. Reducing the thickness of copper pad 100 provides more flexibility in the design of the BGA package and may reduce costs in manufacturing of the package.

In some embodiments, a palladium layer is placed between the nickel layer and either the tin layer or the silver layer. The palladium layer may be formed using, for example, an electroless palladium process.

The embodiments of BGA pads and surface finishes depicted in FIGS. 4 and 5 may be used for integrated circuits such as, but not limited to, graphical processing units (GPUs) and central processing units (CPUs). In some embodiments, the BGA pads and surface finishes depicted in FIGS. 4 and 5 may be used in printed circuit boards (PCBs) or printed wiring boards (PWBs).

In certain embodiments, the embodiments of BGA pads and surface finishes depicted in FIGS. 4 and 5 are CAD (computer-aided design) designed structures or structures formed from a CAD designed process. In certain embodiments, a computer readable storage medium stores a plurality of instructions which, when executed, generates the embodiments of BGA pads and surface finishes depicted in FIGS. 4 and 5. For example, the instructions may provide steps to a process that generates the embodiments of BGA pads and surface finishes depicted in FIGS. 4 and 5.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed:

1. A ball grid array package device, comprising:
a substrate;
a copper pad formed on the substrate;
a nickel layer formed on the copper pad; and
a tin layer formed on the nickel layer.

2. The device of claim 1, wherein the nickel layer is an electroless nickel layer.

3. The device of claim 1, wherein the tin layer is an immersion tin layer.

4. The device of claim 1, further comprising a solder mask formed on the substrate at or around the edges of the copper pad.

5. The device of claim 1, wherein the nickel layer has a thickness between about 5 microns and about 10 microns.

6. The device of claim 1, wherein the tin layer has a thickness between about 1 micron and about 5 microns.

7. The device of claim 1, wherein the nickel layer inhibits intermetallic diffusion between the tin layer and the copper pad.

8. The device of claim 1, wherein the substrate comprises a buried oxide layer.

9. The device of claim 1, wherein the tin layer is bondable to lead-free solder during use.

10. The device of claim 1, wherein the copper pad, the nickel layer, and the tin layer are formed according to a CAD (computer-aided design) designed structure.

11. A ball grid array package device, comprising:
a substrate;
a copper pad formed on the substrate;
a nickel layer formed on the copper pad; and
a silver layer formed on the nickel layer.

12. The device of claim 1, wherein the nickel layer is an electroless nickel layer.

13. The device of claim 1, wherein the silver layer is an immersion silver layer.

14. The device of claim 1, wherein the nickel layer has a thickness between about 5 microns and about 10 microns.

15. The device of claim 1, wherein the silver layer has a thickness between about 1 micron and about 5 microns.

16. The device of claim 1, wherein the nickel layer inhibits intermetallic diffusion between the silver layer and the copper pad.

17. The device of claim 1, wherein the substrate comprises a buried oxide layer.

18. The device of claim 1, wherein the silver layer is bondable to lead-free solder during use.

19. The device of claim 1, wherein the copper pad, the nickel layer, and the silver layer are formed according to a CAD (computer-aided design) designed structure.

20. A ball grid array package fabrication process, comprising:
forming a copper ball grid array pad on a substrate;
forming a solder mask on the substrate around the copper pad;
forming a nickel layer on the copper pad; and
forming a tin layer on the nickel layer.

21. The process of claim 20, further comprising bonding lead-free solder to the tin layer.

22. A ball grid array package, wherein at least one of the ball grid array pads comprises:
a copper pad formed on a substrate;
a nickel layer formed on the copper pad; and
a silver layer formed on the nickel layer.

23. A computer readable storage medium storing a plurality of instructions which, when executed, generate a ball grid array package that comprises:
a copper pad formed on a substrate;
a nickel layer formed on the copper pad; and
a silver layer formed on the nickel layer.

24. A computer readable storage medium storing a plurality of instructions which, when executed, generate a process that comprises:
forming a copper ball grid array pad on a substrate;
forming a solder mask on the substrate around the copper pad;
forming a nickel layer on the copper pad; and
forming a tin layer on the nickel layer.
